(19) United States
(12) Patent Application Publication
(10) Pub. No.: US 2025/0198556 A1
(43) Pub. Date: Jun. 19, 2025

(54) FLUIDIC CONNECTION DEVICE AND FLUIDIC CONNECTION ASSEMBLY COMPRISING SUCH A FLUIDIC CONNECTION DEVICE

(71) Applicant: STAUBLI FAVERGES, Faverges-Seythenex (FR)

(72) Inventors: Serafim Marques Barroca, Albertville (FR); Christophe Durieux, Gilly Sur Isere (FR)

(21) Appl. No.: 18/981,141

(22) Filed: Dec. 13, 2024

(30) Foreign Application Priority Data
Dec. 15, 2023 (FR) 2314303

(51) Int. Cl. F16L 37/50; B05B 3/00; F16L 37/32

(52) U.S. Cl. CPC F16L 37/50; B05B 3/00; F16L 37/32

(57) ABSTRACT

The present invention relates to a fluidic connection device, comprising a flange, and a nozzle through which passes a distal internal channel, and which is configured so as to be fluidically coupled to a complementary connection device. The nozzle, mounted in the flange with the possibility of tilting relative to the flange, comprises a rear end, and a front end. The invention also includes a rod comprising an intermediate internal channel; a front end, mounted in sealed cooperation with the rear end of the nozzle with the possibility of tilting of the rod relative to the nozzle and relative to the flange, for fluidic communication between the distal internal channel of the nozzle and the intermediate internal channel of the rod; and a rear end for fluidic communication between a proximal internal conduit and the intermediate internal channel.

### FIELD

The present invention relates to a fluidic connection device and a fluidic connection assembly comprising such a fluidic connection device.

In the field of temperature control circuits, in particular those designed to cool IT system server installations, using all types of fluids, in particular a heat transfer fluid, at a maximum pressure of 16 bar, it is known practice to connect, by means of a connection assembly, the various elements of the temperature control circuit in a manner such as to establish a fluidic connection therebetween in order to circulate said fluid in the temperature control circuit.

The known fluidic connection assembly comprises at least one first fluidic connection element, for example a male element, and at least one complementary second fluidic connection element, for example a female element, being arranged so as to be coupled with the first fluidic connection element.

However, due to manufacturing and assembly tolerances, the first connection element of the connection assembly and the second complementary element are generally not perfectly aligned, which increases the coupling forces, the risk of jamming and/or wear during connection.

### BACKGROUND

It is known from CN102691844 to use a first nozzle of the connection assembly which comprises a movable valve in the nozzle body and a rear end of the nozzle body provided with a convex spherical surface. The convex spherical surface cooperates in a sealing manner with a spherical ring. A retaining ring locks the nozzle body and prevents it from being withdrawn from the mounting base. A clearance space is provided between the surface of the internal wall of the mounting base and respectively the spherical ring, the retaining ring, the exterior peripheral surface of the nozzle body and such that the nozzle body is able to be tilted relative to the spherical ring whilst the spherical ring is able to move radially relative to the mounting base.

It is also known from EP4155596 to use a deflectable flange in which are housed two first nozzles of the connection assembly, each first nozzle being tiltable relative to the flange and capable of assuming a configuration that is misaligned relative to the flange in order to tolerate an angular misalignment or error when coupling with an associated second connection nozzle of the connection assembly. However, the sealing rings, arranged between the support of the connection assembly and the deflection surface of the flange, increase the friction caused by the deflection movement of the flange, which increases the connection forces.

### SUMMARY

The aim of the invention is therefore to provide a fluidic connection device that tolerates angular and/or radial misalignment or errors at the start of coupling and that limits coupling forces, in particular due to flange deflection.

To this end, the object of the invention relates to a fluidic connection device comprising:
a flange, forming an external front axial surface and an external rear axial surface, opposite the external front axial surface, the external front axial surface and the external rear axial surface being annular, perpendicular to a central longitudinal axis of the flange, and oriented to be faced respectively in a frontward direction parallel to the longitudinal axis of the flange, and in a rearward direction opposite the frontward direction; and
at least one nozzle centered around a longitudinal axis, through which passes a distal internal channel and which is configured so as to be fluidically coupled to a complementary connection device, the nozzle comprising:
a rear end, mounted in an internal housing of the flange; and
a front end, disposed beyond the external front axial surface of the flange in the frontward direction;
the nozzle being mounted in the flange with the possibility of tilting relative to the flange, and with the possibility of limited movement relative to the flange in the frontward and rearward directions and in all the directions radial to the longitudinal axis of the flange; the rear end of the nozzle being integrally secured in movement with the flange radially to the longitudinal axis, allowing for radial clearances between an external collar of the nozzle and the flange, the external collar being cylindrical and arranged at the rear end of the nozzle;
a cover, which forms a rear axial surface capable of cooperating with the external front axial surface of the flange in order to guide a movement of the flange relative to the cover radially to the longitudinal axis of the flange.

According to the invention, the fluidic connection device further includes a rod comprising:
an intermediate internal channel;
a front end, mounted in sealed cooperation with the rear end of the nozzle with the possibility of tilting of the rod relative to the nozzle and relative to the flange, the front end of the rod being integrally secured to the rear end of the nozzle along the longitudinal axis of the nozzle, allowing for operating clearances, and the front end of the rod being integrally secured to the rear end of the nozzle radially to the longitudinal axis of the nozzle, allowing for operating clearances, for fluidic communication between the distal internal channel of the nozzle and the intermediate internal channel of the rod; and
a rear end disposed beyond the flange, along the rearward direction for fluidic communication between the intermediate internal channel of the rod and a proximal internal conduit, relative to which the cover is intended to be immovable; with the intermediate internal channel passing through the rod from the front end of the rod to the rear end of the rod.

Thanks to the invention, in particular thanks to the presence of the rod and the sealed connection between the distal internal channel and the intermediate internal channel, which form a sealed fluid passage from the front end of the nozzle to the rear end of the rod, the flange is no longer involved in the sealing of the connection. In particular, when the flange is mounted in a support, the invention makes it possible to fluidically isolate the flange from the distal internal channel of the nozzle and from the intermediate internal channel of the rod and renders unnecessary the mounting of a seal between the front axial surface of the flange and the support or between the rear axial surface of the flange and the support. This absence of a seal serves to limit friction during radial movement of the flange in the support and thus to limit connection forces.

According to other advantageous aspects of the invention, the fluidic connection device comprises one or more of the following characteristic features, taken into consideration individually or in accordance with all technically feasible combinations:
the front end of the rod is received in a sealed manner in an internal housing of the rear end of the nozzle;
the rod comprises a tubular body and a front ring, which in a sealing manner surrounds the tubular body of the rod in order to form the front end of the rod and which, in a mounted configuration of the rod as mounted in the internal housing, presents an external surface in the form of a portion of a sphere which cooperates by means of form-fitting with an internal surface in the form of a portion of a sphere, of the internal housing of the rear end of the nozzle; and is able to effect a rearward abutment against an abutment surface formed by the partially spherical internal surface of the internal housing and delimited by an opening of the nozzle that opens onto the rear of the nozzle and, at the front, into the internal housing of the nozzle, said opening extending, in a plane perpendicular to the longitudinal axis of the nozzle, over a cross section that is greater than the external cross section of the front ring, considered in a longitudinal plane passing through the longitudinal axis of the nozzle and in the mounted configuration of the rod as mounted in the internal housing;
no sealing ring is interposed directly between the flange and the nozzle;
a first spring, which is interposed between the flange and the nozzle and which resiliently biases the nozzle relative to the flange, to a position wherein the external collar of the nozzle is abutted frontward against an internal surface of the flange delimiting the internal housing, and the longitudinal axis of the flange is coaxial with the longitudinal axis of the nozzle;
a support body, having the cover attached therewith, that forms a front axial surface which delimits, with the rear axial surface of the cover, a housing that receives the flange, the front axial surface being capable of guiding the movement of the flange relative to the support body, radially to the longitudinal axis of the flange, by cooperation with the external rear axial surface of the flange; and the proximal internal conduit, which is centred around a central longitudinal axis, which opens into the housing of the support body in the frontward direction, and which receives the rear end of the rod for fluidic communication between the intermediate internal channel of the rod and the proximal internal conduit;
a recentring device, which resiliently biases the flange to a position wherein the longitudinal axis of the flange is coaxial with the central longitudinal axis of the proximal internal conduit;
the recentring device comprises a recentring ring, which is arranged in the proximal internal conduit and is movable in translational motion relative to the support body along the central longitudinal axis of the proximal internal conduit; and a second spring, which pushes a front surface of the recentring ring into contact with a rear surface of the flange; and the rear surface of the flange is a frustoconical surface centred on the longitudinal axis of the flange and/or the front surface of the recentring ring is a frustoconical surface centred on the central longitudinal axis of the proximal internal conduit;
a sealing ring, that is integrally secured to the rod along the central longitudinal axis of the proximal internal conduit and in sealed contact with an internal radial surface of the proximal internal conduit of the support body;
the rear end of the rod is mounted in a slider in a sealed manner, with the possibility of tilting relative to the slider; the rear end of the rod is integrally secured to the slider along the longitudinal axis of the proximal internal conduit, allowing for operating clearances; and the rear end of the rod is integrally secured to the slider radially to a longitudinal axis of the rod allowing for operating clearances; and the slider has a cylindrical external radial surface and is mounted in the proximal internal conduit with the possibility of movement relative to the support body along the central longitudinal axis of the proximal internal conduit;
the intermediate internal channel of the rod is delimited by an internal surface, that is frustoconical and outwardly flared towards the exterior of the intermediate internal channel, at the front end of the rod, and at the rear end of the rod respectively;
a length of the rod, as measured between the front end and the rear end of the rod along a longitudinal axis of the rod, is strictly less than a length of the nozzle, as measured between the front end and the rear end of the nozzle along the longitudinal axis of the nozzle;
a valve disposed in the distal internal channel of the nozzle, which is movable relative to the nozzle along the longitudinal axis of the nozzle between an advanced position for closing the distal internal channel and a retracted position for opening the distal internal channel.

The invention also relates to a fluidic connection assembly comprising the fluidic connection device as defined above and the complementary connection device, configured so as to be coupled with the nozzle of the fluidic connection device.

Preferably, the complementary connection device includes a main body, that comprises a stepped internal radial surface, with the nozzle comprising a stepped external radial surface, and with the stepped internal radial surface and the stepped external radial surface cooperating, in the coupled configuration, by means of form-fitting.

### BRIEF DESCRIPTION OF THE DRAWINGS

The invention will become more clearly apparent from the description which follows, provided solely by way of non-limiting example, and made with reference to the drawings in which:

FIG. 1 is a longitudinal cross section of a fluidic connection assembly comprising a connection device and a complementary connection device according to a first embodiment of the invention, with the connection devices being represented in a configuration characterising start of coupling between the two devices.

FIG. 2 is a transverse cross section of the fluidic connection assembly shown in FIG. 1 along cross sectional plane II-II shown in FIG. 1.

FIG. 3 is a transverse cross section of the fluidic connection assembly shown in FIG. 1 along cross sectional plane III-III shown in FIG. 1.

FIG. 4 is a longitudinal cross section of the fluidic connection assembly shown in FIG. 1, with the connection devices being represented in a first intermediate coupling configuration.

FIG. 5 is a longitudinal cross section of the fluidic connection assembly shown in the previous figures, with the connection devices being represented in a second intermediate coupling configuration.

FIG. 6 is a longitudinal cross section of the fluidic connection assembly shown in the previous figures, with the connection devices being represented in a coupled configuration.

FIG. 7 is a longitudinal cross sectional view of a fluidic connection assembly comprising a connection device and a complementary connection device according to a second embodiment of the invention, with the connection devices being represented in a configuration characterising the start of coupling between the two devices.

FIG. 8 is a longitudinal cross sectional view of the fluidic connection assembly shown in FIG. 7, with the connection devices being represented in a first intermediate coupling configuration.

FIG. 9 is a longitudinal cross sectional view of the fluidic connection assembly shown in FIG. 7, with the connection devices being represented in a second intermediate coupling configuration.

FIG. 10 is a longitudinal cross sectional view of the fluidic connection assembly shown in FIG. 7, with the connection devices being represented in a coupled configuration.

### DETAILED DESCRIPTION

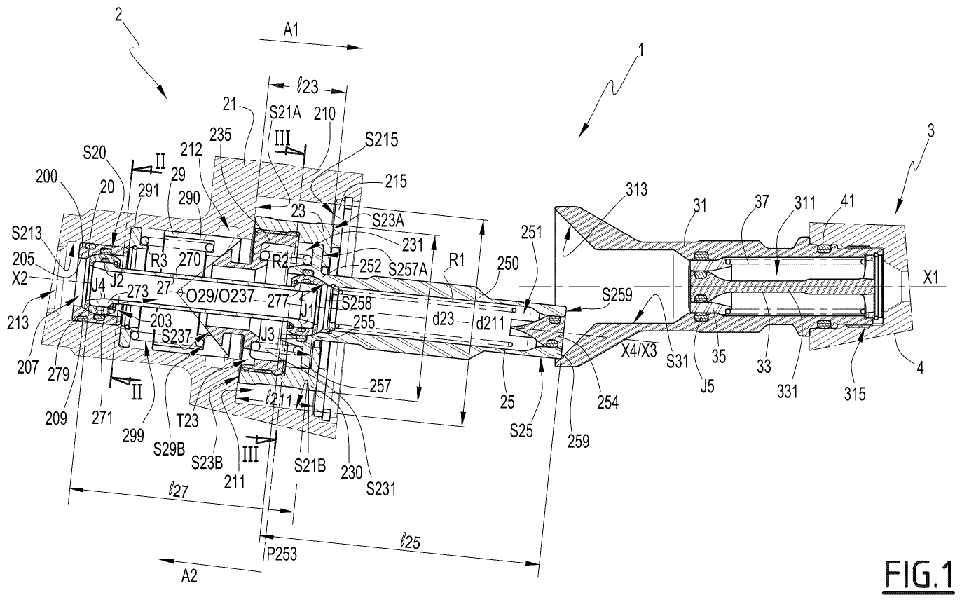

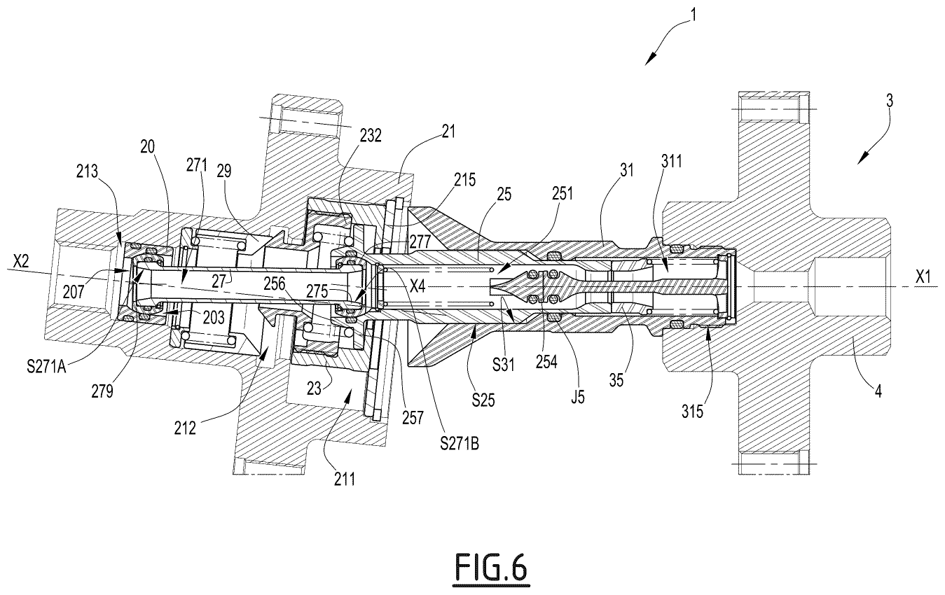

A fluidic connection assembly 1, according to a first embodiment of the invention, as represented in FIGS. 1 to 6, comprises a fluidic connection device 2, in this case a male fluidic connection device, and a complementary connection device 3, in this case a female connection device. In FIG. 6, the complementary connection device 3 receives in a press-fitted manner the fluidic connection device 2, in a coupled configuration.

The complementary connection device 3 comprises a main body 31, in this case a female body; a central piston 33; an annular valve 35; and a spring 37.

The main body 31 is tubular such as to have running right through it an internal channel 311 centred on a longitudinal axis X1. The internal channel 311 is delimited by a front mouth surface 313 that is frustoconical and by an internal radial surface S31 which is advantageously stepped, that is to say having a plurality of internal diameters that progressively increase in size in the direction of the mouth surface 313.

The main body 31 additionally comprises a threaded rear surface 315. The threading of the rear surface 315 enables the main body 31 to be screwed onto a support 4, which is itself connected to a pipe or hose, with the sealing of the assembly between the main body 31 and the support 4 being ensured by a sealing ring 41 interposed between the rear surface 315 and the support 4.

The central piston 33 consists of a rotational body 331 centred around the longitudinal axis X1; the body 331 is mounted fixedly along the longitudinal axis X1 in relation to the main body 31 in the internal channel 311.

The annular valve 35 is mounted in the internal channel 311 and is movable relative to the main body 31 and the piston 33 along the longitudinal axis X1 between an advanced position for closing the internal channel 311 and a retracted position for opening the internal channel 311. In its advanced position, the annular valve 35 cooperates in a sealing manner with a cylindrical seat formed on the main body 31 and with the piston 33.

The spring 37 is interposed between the central piston 33 or the main body 31 and the annular valve 35. The spring 37 pushes the annular valve 35 to its advanced position.

The fluidic connection device 2 comprises a flange 23, a nozzle 25, a rod 27, a support 21 and preferably a slide 20.

The support 21 comprises a tubular support body 210, centred over a longitudinal axis X2. The support 21 includes a first front internal axial surface S21A, which is perpendicular to the longitudinal axis X2, and a second cylindrical internal radial surface S21B, which is centred over the longitudinal axis X2.

The support 21 comprises a cover 215 which is fastened on the support body 210 by a stop segment or, as a variant, by screwing. The first and second surfaces S21A, S21B of the support 21 and a rear axial surface S215 of the cover 215, which is parallel and opposite to the first front internal axial surface S21A, delimit an internal housing 211 that has an internal diameter d211. The cover 215 closes the housing 211 along a frontward direction A1 parallel to the longitudinal axis X2.

For the purposes of this description, terms such as ‘axial’, ‘radial’ and ‘longitudinal’ are defined in relation to the central or longitudinal axis of the element to which they pertain. For example, with regard to support 21, terms such as ‘axial’, ‘radial’ and ‘longitudinal’ are defined in relation to the axis X2. In this case, for example, an axial surface of the support 21 extends perpendicularly to the axis X2, a radial surface of the support 21 extends parallely to the axis X2 and around the axis X2. Terms such as ‘front’ and ‘distal’, when they pertain to the fluidic connection device 2, refer to the frontward direction A1. Terms such as ‘rear’ and ‘proximal’, when they pertain to the fluidic connection device 2, refer to a rearward direction A2 that is opposite to the frontward direction A1. A ‘front surface’ is oriented facing the frontward direction, a ‘rear surface’ is oriented facing the rearward direction.

The support 21 also comprises a proximal internal conduit 213 passing through the support body 210 and opening, in the frontal direction A1, into the housing 211. The proximal internal conduit 213 is centred around the longitudinal axis X2. The proximal internal conduit 213 comprises a peripheral cavity 212, formed in a recess, and an internal radial surface S213, that is to say a surface whereof the normal at any point is orthogonal to the longitudinal axis X2. At the rear, the proximal internal conduit 213 is intended to be connected to a pipe or hose. By being fixed onto the support body 210, the cover is fixed relative to the proximal internal conduit 213.

The slider 20 comprises an annular body 200, centred around a longitudinal axis, which, in operation, is coincident, allowing for radial clearances, with the longitudinal axis X2 and which will therefore be considered to be the longitudinal axis X2 hereinafter for the sake of convenience.

The slider 20 comprises a cylindrical external radial surface S20, which cooperates with reduced radial clearance with the internal radial surface S213 of the proximal internal conduit 213, and an internal housing 207 in the form of a portion of a sphere which are centred around the longitudinal axis X2, as well as an opening 203 and a rear shoulder 205. The opening 203 opens out onto the front of the slide 20 and, at the rear, into the internal housing 207. The opening 203 is elongated perpendicularly to the longitudinal axis X2. The opening 203 has a width L203, as measured in a direction orthoradial to the longitudinal axis X2, and a height h203, as measured both perpendicularly to the longitudinal axis X2 and perpendicularly to the width L203. The height h203 is strictly greater than the width L203 of the opening 203.

The slider 20 is housed in the proximal internal conduit 213 of the support 21 and a sealing ring 209 is interposed radially between the cylindrical external radial surface S20 of the slider 20 and the internal radial surface S213 of the proximal internal conduit 213. Preferentially, the sealing ring 209 is borne by the cylindrical external radial surface S20 of the slider 20 in a manner such that the sealing ring 209 is integrally secured to the rod 27 along the longitudinal axis X5.

The flange 23 comprises a tubular body 230 centred around a longitudinal axis X3, which is parallel to the longitudinal axis X2 in the configuration of the flange 23 as mounted in the support 21. The frontal A1 and rearward A2 directions are therefore also applicable to the longitudinal axis X3. Preferably, the tubular body 230 is formed by screwing a plurality of parts together.

The flange 23 comprises an external front axial surface S23A and an external rear axial surface S23B which are planar, parallel to each other and perpendicular to the longitudinal axis X3. The external front axial surface S23A and the external rear axial surface S23B are annular surfaces centred around the longitudinal axis X3. The external front axial surface S23A and the external rear axial surface S23B extend at least partially at the same radial level to the longitudinal axis X3.

The flange 23 also defines an internal housing 231 centred around the longitudinal axis X3. The internal housing 231 is delimited by an internal surface S231 facing in the rearward direction A2, by a rear internal shoulder 232, by a counterbore 235, by a rear internal radial surface and by an internal radial surface 233 arranged along the longitudinal axis X3 between the internal surface S231 and the rear internal shoulder 232. The internal surface S231 delimits the internal housing 231 in the frontward direction A1. The internal housing 231 opens out at the front of the flange 23 and at the rear of the flange 23.

The flange 23 also has holes T23 enabling the internal housing 231 of the flange 23 to communicate with the exterior of the flange 23.

Advantageously, the flange 23 comprises a tubular rear protuberance 237 which protrudes from the external rear axial surface S23B of the flange 23 rearwards into the proximal internal conduit 213 and which forms the rear internal radial surface of the flange 23. Advantageously, the rear protuberance 237 forms a rear surface S237. Advantageously, the rear surface S237 is frustoconical, converging along the rearward direction A2 and is centred about the longitudinal axis X3, and has an angular opening O237.

The flange 23 is mounted in the housing 211 with the possibility of having radial movement relative to the support 21 in all directions radial to the longitudinal axis X2.

A maximum external diameter d23 of the flange 23, as measured perpendicularly to the longitudinal axis X3, is strictly less than the internal diameter d211 of the housing 211, advantageously between 15% and 25% less than the internal diameter d211 of the housing 211, preferably 20% less than the internal diameter d211 of the housing 211.

A longitudinal dimension 123 of the flange 23, as measured parallelly to the longitudinal axis X3 between the external front axial surface S23A and the external rear axial surface S23B of the flange 23, is substantially equal to a longitudinal dimension 1211 of the housing 211, as measured parallelly to the longitudinal axis X2 between the first front axial surface S21A of the support 21 and the rear axial surface S215 of the cover 215.

After assembly of the fluidic connection device 2, the cooperation by means of plane-to plane contact, allowing for assembly clearances, between the external front axial surface S23A and the rear axial surface S215, and between the external rear axial surface S23B and the first front axial surface S21A, facilitates and guides the movement of the flange 23 in the housing 211 radially to the longitudinal axis X3. In the event of significant radial movement of the flange 23 relative to the longitudinal axis X2, the rear protuberance 237 becomes lodged in the peripheral cavity 212 of the proximal internal conduit 213.

Preferably, the flange 23 is assembled by screwing a plurality of parts together. Preferably, the external front axial surface S23A, the external rear axial surface S23B, the internal radial surface 233, and the internal surface S231 are formed on a first part of the flange 23, while the protuberance 237, the shoulder 232 and the counterbore 235 are formed on a second part of the flange 23 that is screwed onto the first part on the rear of the first part. The first and second parts may be made from two different materials, for example polymer for the first part and metal for the second part. The holes T23 are used to assemble the two parts of the flange 23 by means of a tool. The flange 23, and in particular the external front axial surface S23A and the external rear axial surface S23B, has no sealing ring. The first front internal axial surface S21A and the rear axial surface S215 of the cover 25 also have no sealing ring. Thus no sealing ring is interposed directly between the flange 23 and the support 21 or the cover 215.

The nozzle 25 comprises a male tubular body 250, centred about a longitudinal axis X4, with a distal internal channel 251 passing right through it along the longitudinal axis X4. The tubular body 250 comprises an external radial surface S25 that is arranged in front of the support 21 and which, advantageously, is stepped, that is to say it has a plurality of external diameters that progressively decrease in dimension in the frontward direction A1.

The nozzle 25 houses a valve 254 which is mounted so as to be movable in the distal internal channel 251, and a spring R1. The valve 254 is movable within the tubular body 250 of the nozzle 25, along the longitudinal axis X4, between an advanced position for closing the distal internal channel 251 and a retracted position for opening the fluid passage in the distal internal channel 251. The valve 254 is integrally secured to the tubular body 250 radially to the longitudinal axis X4. The valve 254 is pushed to its advanced position by the spring R1 that is interposed between a washer bearing back against the tubular body 250 and the valve 254. In its advanced position, the valve 254 cooperates in a sealed manner with a seat formed on a front end 259 of the tubular body 250.

The tubular body 250 comprises a cylindrical external collar 257 disposed at a rear end 252 of the tubular body 250. The external collar 257 comprises a front surface S257A and a rear surface S257B that are parallel to each other and perpendicular to the longitudinal axis X4. An external diameter d257 of the external collar 257, centred on the longitudinal axis X4, is greater than the diameters of the external radial surface S25. The tubular body 250 also comprises a skirt 256 that extends rearwardly from the external collar 257 and has an external diameter that is smaller than the external diameter d257.

The collar 257 faces the internal surface S231 at the front, and the internal shoulder 232 at the rear. The nozzle 25 is therefore mounted in the flange 23 with the possibility of limited movement relative to the flange 23 in the frontward A1 and rearward A2 directions.

The rear end 252 of the nozzle 25 comprises an internal housing 258 which opens out into the distal internal channel 251 in the frontward direction A2 at a front shoulder 255 of the tubular body 250. An opening 253 opens out onto the rear of the tubular body 250 of the nozzle 25 and, at the front, into the internal housing 258. A plane P253 that is perpendicular to the longitudinal axis X4 and coplanar with cross sectional plane III-III intersects the opening 253. The internal housing 258 of the nozzle 25 is delimited by an internal surface S258 in the form of a portion of a sphere centred around the longitudinal axis X4. The opening 253 is elongated perpendicularly to the longitudinal axis X4. The opening 253 has a width L253 as measured in a direction orthoradial to the longitudinal axis X4, and a height h253 as measured perpendicularly to the longitudinal axis X4 and perpendicularly to the width L253.

The rear end 252 of the nozzle 25 is housed in the internal housing 231 and is arranged in front of the external rear axial surface S23B. In particular, in the uncoupled configuration of the fluidic connection device 2, the external collar 257 is in plane-to-plane contact with the internal surface S231 of the flange 23. The radial clearance of the connection between the nozzle 25 and the flange 23, which corresponds to the radial clearance between the internal radial surface 233 and the external radial surface of the collar 257, is less than 1% of the external diameter d257 of the external collar 257, as measured perpendicularly to the longitudinal axis X4, for example for an external diameter d257 of the external collar 257 of 24.5 mm, the radial clearance is of the order of 0.1 to 0.2 mm. The tubular body 250 thus cooperates with the flange 23 with reduced radial clearance and is mounted with the possibility of tilting in the flange 23 while having limited relative movement with the flange 23 in all directions radial to the longitudinal axis X3.

A spring R2 rests on the flange 23 in the counterbore 235 and on the rear surface S257B of the external collar 257 of the nozzle 25, being guided radially by the external radial surface of the skirt 256. The spring R2 pushes the front surface S257A of the external collar 257 of the nozzle 25 forwards to a position in which the external collar 257 is in front longitudinal abutment against the internal surface S231 of the flange 23, with the longitudinal axis X4 of the nozzle 25 in a coaxial position—allowing for radial clearances between the external collar 257 and the internal radial surface 233 of the flange 23—with the longitudinal axis X2 of the flange 23, a position which is reached in the uncoupled configuration. The internal surface S231 of the flange 23 limits the forward movement of the nozzle 25 relative to the flange 23. The rear end 252 of the nozzle 25 is integral in movement with the flange 23 radially to the longitudinal axis X2, allowing for radial clearances between the external collar 257 and the flange 23.

The nozzle 25 partially projects beyond the flange 23 and the support 21 in the frontward direction A1 and passes through the cover 215. To this end, the cover 215 has a central opening that is compatible with the movements of the flange 23 and the nozzle 25 relative to the support 21.

No sealing ring is interposed directly between the flange 23 and the nozzle 25, in particular between the external radial surface of the rear end 252 of the nozzle 25 and the flange 25, in particular between the collar 257 and the internal radial surface 233 of the flange 23. This facilitates the inclining of the nozzle 25 in the flange 23.

The rod 27 has a tubular body 270 that is centred around a longitudinal axis X5, is single-membered and delimits an intermediate internal channel 271 passing right through the tubular body 270 along the longitudinal axis X5. At a rear end 273 of the rod 27, the intermediate internal channel 271 is delimited by a rear internal surface S271A which is frustoconical and diverges towards the rear and outwards towards the exterior of the intermediate internal channel 271. At a front end 275 of the rod 27, the intermediate internal channel 271 is delimited by a front internal surface S271B which is frustoconical and diverges towards the front and outwards towards the exterior of the intermediate internal channel 271. The intermediate internal channel 271 has neither a valve nor any other means of closure.

A length 127 of the rod 27, as measured parallelly to the longitudinal axis X5 between the front end 275 and the rear end 273 of the rod 27, is advantageously at least equal to 0.6 times, preferably at least equal to 0.75 times, a length 125 of the nozzle 25, as measured between a front face S259 of the front end 259 of the nozzle 25 and a rear face of the nozzle 25. The length 127 of the rod 27 is strictly less than the length 125 of the nozzle 25. The length 127 of the rod 27 serves to limit the tilting of the rod 27 relative to the nozzle 25 in order to limit the stresses on the seals interposed between the rod 27 and the nozzle 25 in the event of maximum angular fault. Advantageously, the length 127 of the rod 27 is selected to be close to the length 125 of the nozzle 25 in order to limit the radial space required, in the support 21 and in the flange 23, for the tilting of the rod 27 when the maximum radial movement of the flange 23 in the support 21 is reached. In practice, the maximum inclination of the rod 27 in relation to the nozzle 25 is approximately 6° and the maximum inclination of the nozzle 25 in relation to the flange 23 is approximately 6°.

The rod 27 comprises a front ring 277 fitted around a front portion 280 of the tubular body 270, integrally secured to the tubular body 270 along the longitudinal axis X5 and forming the front end 275 of the rod 27. The front ring 277 forms an external surface S277 in the form of a portion of a sphere having an external diameter d277, centred on the longitudinal axis X5 and extending all around the longitudinal axis X5 in the mounted configuration with the front ring 277 mounted on the tubular body 270. A sealing ring J1 is radially interposed, relative to the longitudinal axis X5, between the front ring 277 and the front portion 280 of the tubular body 270 of the rod 27 and ensures sealed cooperation between the tubular body 270 and the ring 277.

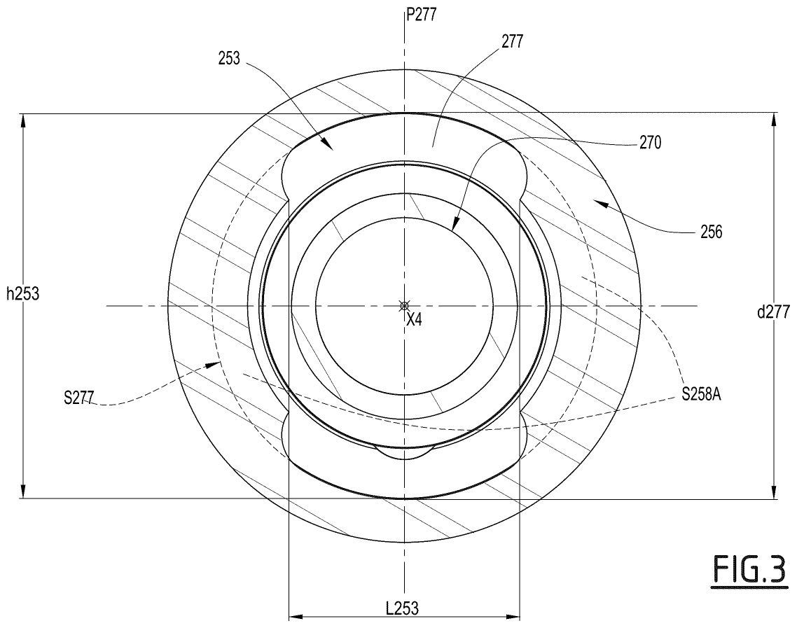

A thickness e277 of the front ring 277, as measured parallely to the longitudinal axis X4, in the mounted configuration of the front ring 277 as mounted in the nozzle 25 and when the longitudinal axis X4 is coaxial with the longitudinal axis X5, as shown in FIG. 1, is less than the width L253 of the opening 253 of the rear end 252 of the nozzle 25. The width L253 is strictly less than the external diameter d277. The external diameter d277 of the front ring 277 measures less than the height h253 of the opening 253 in the rear end 252 of the nozzle 25 and strictly more than the width L253 of the opening 253. Thus the external cross section of the ring 277, considered in a longitudinal plane P277 passing through the longitudinal axis X4 in the mounted configuration of the rod 27 as mounted in the nozzle 25 and defined by the thickness e277 and the external diameter d277, is smaller than the cross section of the opening 253 when considered in a plane perpendicular to the longitudinal axis X4, for example in the perpendicular plane P253, and defined by the width L253 and the height h253. The cross section of the opening 253 can be seen in FIG. 3, in which the snap ring 284 has been omitted. The external section of the rear ring 277 can be seen in FIGS. 1 and 4 to 6.

The longitudinal connection between the tubular body 270 and the nozzle 25 is brought about by the front ring 277 interposed along the longitudinal axis X5 between the front shoulder 255 and the opening 253 of the nozzle 25. The rod 27 is assembled to the nozzle 25 by means of engagement of the front ring 277 in the internal housing 258 of the rear end 252 of the nozzle 25 by the front ring 277 engaging longitudinally through the opening 253 all the way into the internal housing 258, the front ring 277 being oriented such that its thickness e277 is oriented in a plane perpendicular to the longitudinal axis X4. This is possible because the external cross section of the ring 277 is smaller than the cross section of the opening 253. Then, in the internal housing 258, the front ring 277 is rotated about an axis perpendicular to the longitudinal axis X4 and parallel to the dimension along which the height h253 of the opening 253 of the rear end 252 of the nozzle 25 is at a maximum, in a manner such as to replace the front ring 277 with its thickness e277 parallel to the longitudinal axis X4. The front ring 277 is then able to effect a rearward abutment against an abutment surface S258A formed by the internal surface S258 of the internal housing 258 and delimited by the opening 253. As can be seen in FIG. 3, the surface S258A is formed on a rear shoulder of the tubular body 250 through which the opening 253 passes, with this rear shoulder not extending all the way around the longitudinal axis X4 due to the presence of the opening 253. The surface S258A is a front surface. The tubular body 270 is then engaged in the front ring 277 which is provided with the seal J1, in particular through the opening 253, until it effects a frontward abutment against a shoulder of the front ring 277, and a snap ring 284 is set in place between an external shoulder of the front portion 275 of the tubular body 270 and the front ring 277 in order to limit the movement of the tubular body 270 towards the rear of the front ring 277. The front end 275 of the rod 27 is therefore mounted in the nozzle 25 with the possibility of limited movement relative to the nozzle 25 in all directions parallel to the longitudinal axis X4. In other words, allowing for operating clearances, the front end 275 of the rod 27 is integrally secured to the rear end 252 of the nozzle 25 along the longitudinal axis X4.

During assembly, a sealing ring J3 is radially interposed between the front ring 277 and the rear end 252 of the nozzle 25. The sealing ring J3 ensures sealed cooperation between the front end 275 of the rod 27 and the tubular body 250 whatever the relative position of inclination between the nozzle 25 and the rod 27. The cooperation by means of form-fitting between the external surface S277 of the front ring 277 and the internal surface S258 enables the tilting motion of the rod 27 relative to the nozzle 25, that is, an inclination of the longitudinal axis X5 relative to the longitudinal axis X4 in all planes perpendicular to the longitudinal axis X4. In addition, thanks to the cooperation between the external surface S277 of the front ring 277 and the internal surface S258, the front end 275 of the rod 27 is mounted in the nozzle 25 with the possibility of limited movement relative to the nozzle 25 in all directions radial to the longitudinal axis X4. In other words, allowing for operating clearances, the front end 275 of the rod 27 is integrally secured to the rear end 252 of the nozzle 25 radially to the longitudinal axis X4 and in particular is integral with the movements of the nozzle 25 relative to the support 21 radially to the longitudinal axis X4.

In the mounted configuration of the rod 27 as mounted in the nozzle 25, the rod 27 is connected to the nozzle 25 by means of a ball-and-socket joint due to the cooperation of the surfaces S277 and S258.

The rod 27 is disposed partially in the internal housing 231 in the flange 23. In other words, a portion of the rod 27 is enclosed within the flange 23. The rod 27 projects partially out of the flange 23 rearwardly in relation to the external rear axial surface S23B and in relation to the rear surface S237 and out of the nozzle 25 rearwardly in relation to the rear end 252 of the nozzle 25.

The rod 27 also comprises a rear ring 279 that is fitted around the rear portion 282 of the tubular body 270, integrally secured to the tubular body 270 along the longitudinal axis X5 and forming the rear end 273 of the rod 27. The rear ring 279 forms an external surface S279 in the form of a portion of a sphere having an external diameter d279, centred around the longitudinal axis X5 and extending all around the longitudinal axis X5 in a mounted configuration of the rear ring 279 as mounted on the tubular body 270. A sealing ring J2 is radially interposed, relative to the longitudinal axis X5, between the rear ring 279 and the rear portion 282 of the tubular body 270 of the rod 27.

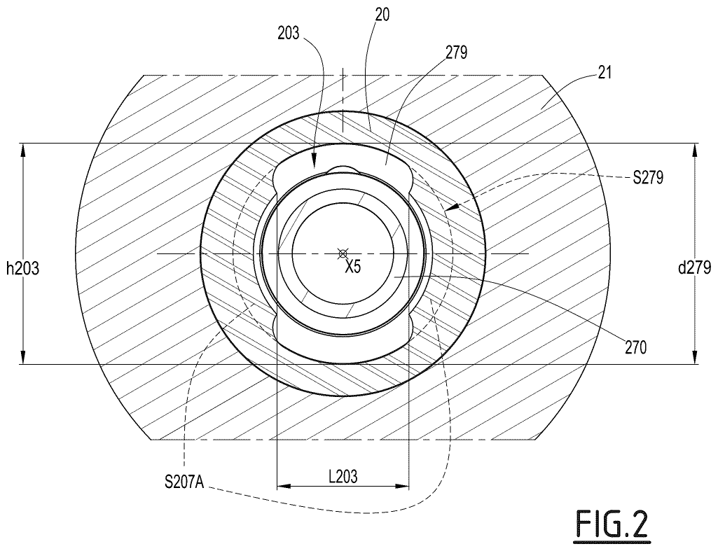

A thickness e279 of the rear ring 279, as measured parallely to the longitudinal axis X2, in the mounted configuration of the rod 27 as mounted in the slider 20 and when the longitudinal axis X2 is coaxial to the longitudinal axis X5, as represented in FIG. 1, is less than the width L203 of the opening 203 of the slider 20. The width L203 measures strictly less than the external diameter d279. The external diameter d279 of the rear ring 279, as measured perpendicularly to the longitudinal axis X5, is less than the height h203 of the opening 203 of the slider 20. Thus the external cross section of the ring 279, considered in a longitudinal plane passing through the longitudinal axis X2 in the mounted configuration of the rod 27 as mounted in the slider and defined by the maximum thickness e279 and the external diameter d279, is smaller than the cross section of the opening 203 considered in a plane perpendicular to the longitudinal axis X2 and defined by the width L203 and the height h203. The cross section of the opening 203 can be seen in FIG. 2, in which the snap ring 286 has been omitted. The external cross section of the rear ring 279 can be seen in FIGS. 1 and 4 to 6.

The longitudinal connection between the tubular body 270 and the slider 20 is brought about by the rear ring 279 which is interposed along the longitudinal axis X5 between the rear shoulder 205 and the opening 203 of the slider 20. The rod 27 is assembled to the slider 20 by means of the rear ring 279 engaging longitudinally in the slider 20 all the way into the internal housing 207 through the opening 203, the rear ring 279 being oriented in a manner such that its thickness e279 is oriented in a plane perpendicular to the longitudinal axis X2. This is possible because the external cross section of the ring 279 is smaller than the cross section of the opening 203. Then, in the internal housing 207, the rear ring 279 is rotated about an axis perpendicular to the longitudinal axis X2 and parallel to the dimension along which the height h203 of the opening 203 of the slider 20 is maximum, in a manner such as to replace the rear ring 279 with its thickness e279 parallel to the longitudinal axis X2. The rear ring 279 is then able to effect a frontward abutment against an abutment surface S207A formed by the internal surface of the internal housing 207 and delimited by the opening 203. The tubular body 270 is then engaged in the rear ring 279 that is fitted with the sealing ring J2 until it comes to abut in the rear against a shoulder of the rear ring 279, and a snap ring 286 is then set in place between an external shoulder of the rear portion 273 of the tubular body 270 and the ring 279 in order to limit the movement of the tubular body 270 towards the front of the rear ring 279. The rear end 273 of the rod 27 is therefore mounted in the slider 20 with the possibility of limited movement relative to the slider 20 along the frontward A1 and rearward A2 directions. In other words, allowing for operating clearances, the rear end 273 of the rod 27 is integrally secured to the slider 20 along the longitudinal axis X2.

During assembly, a sealing ring J4 is radially interposed between the rear ring 279 and the slider 20. The cooperation by means of form-fitting between the external surface S279 of the rear ring 279 and the internal surface of the internal housing 207 enables a tilting motion of the rod 27 in relation to the slider 20, and therefore in relation to the support 21, that is, an inclination of the longitudinal axis X5 in relation to the longitudinal axis X2 in all planes perpendicular to the longitudinal axis X2. In particular, in the mounted configuration of the rod 27 as mounted in the slider 20, the rod 27 is connected to the slider 20 by means of a ball-and-socket joint due to the cooperation of the external surface S279 with the internal surface of the internal housing 207.

Furthermore, thanks to the cooperation between the external surface S279 of the front ring 279 and the internal surface of the internal housing 207, the rear end 273 of the rod 27 is mounted in the slider 20 with the possibility of limited movement relative to the slider 20 in all directions radial to the longitudinal axis X5. In other words, allowing for operating clearances, the rear end 273 of the rod 27 is integrally secured to the slider 20 radially to the longitudinal axis X5. In the mounted configuration of the rod 27 as mounted in the slider 20, whatever the relative position of the rod 27 in relation to the slider 20, the sealing ring J4 ensures sealed cooperation between the rear end 273 of the rod 27 and the slider 20, and the proximal internal conduit 213 is in fluidic communication with the intermediate internal channel 271. A sealing barrier is thus formed in order to prevent fluidic communication between the housing 211 or the housing 231 and the intermediate internal channel 271. More precisely, only the portion of the proximal internal conduit 213 that is disposed at the rear of the sealing ring 209 is in fluidic communication with the intermediate internal channel 271. This portion of the proximal internal conduit 213 in fluidic communication with the intermediate internal channel 271 is disposed at the rear of the flange 23 and, in particular, disposed at the rear of the recentring device 299.

An external diameter d273 of the rear end 273 of the rod 27, respectively an external diameter d275 of the front end 275 of the rod 27, is strictly smaller, preferably at least 2 times smaller, than the maximum external diameter d23 of the flange 23. The external diameter d273 of the rear end 273 of the rod 27, respectively the external diameter d275 of the front end 275 of the rod 27, is strictly smaller than the external diameter d257 of the external collar 257 of the nozzle 25.

The movement of the rod 27 along the longitudinal axis X2 is limited, in relation to the nozzle 25 and in relation to the slider 20, respectively by the rear shoulder 205 of the slider 20 and the abutment surface S207A, and by the front shoulder 255 of the nozzle 25 and the abutment surface S258A.

The rear end 273 of the rod 27 is received in the proximal internal conduit 213 at the rear of the internal housing 231. In particular, the rear end 273 is disposed beyond the flange 23, along the rearward direction A2. The proximal internal conduit 213 accommodates the rear end 273 of the rod 27 in a sealed manner by means of the slider 20 and the sealing rings 209 and J4. A rear seal is then formed between the rod 27 and the support 21 while the proximal internal conduit 213 is in fluidic communication with the intermediate internal channel 271.

The flange 23, the nozzle 25 and the rod 27 are, preferentially, positioned in place in the support body 210 of the support 21 from the front of the support body 210 before the cover 215 is screwed or fastened by means of a stop segment on to the support body 210. Advantageously, the fluidic connection device 2 has a radially compact construction.

The fluidic connection device 2 advantageously includes a recentring device 299 that comprises a recentring ring 29 and a spring R3, both of which are housed in the proximal internal conduit 213 of the support 21.

The recentring ring 29 comprises an annular body 290, centred around a longitudinal axis, which, in operation, is coincident, allowing for radial clearances, with the longitudinal axis X2 and which will therefore be considered to be the longitudinal axis X2 hereinafter for the sake of convenience.

The recentring ring 29 advantageously comprises a front surface S29A that is frustoconical and converges towards the rear. The front surface S29A has an angular opening O29 similar to the angular opening O237 of the rear surface S237 of the protuberance 237.

The recentring ring 29 is mounted so as to be movable in translational motion along the longitudinal axis X2 in the proximal internal conduit 213 of the support 21 and is guided radially by the proximal internal conduit 213. The radial clearance does not allow any movement radial to the longitudinal axis X2 of the recentring ring 29 in the proximal internal conduit 213.

After assembly of the fluidic connection device 2, the front surface S29A is in surface contact with the rear surface S237 of the protuberance 237.

After assembly of the fluidic connection device 2, the spring R3 is housed between, at the rear—a bearing ring 291 bearing rearwards against the support 21, and at the front—a rear surface S29B of the recentring ring 29. The spring R3 pushes the conical front surface S29 in the direction of the rear surface S237 of the flange 23. Due to the form-fitting connection between the front surface S29A and the rear surface S237, the spring R3 exerts a radial elastic return force on the flange 23 towards a centred position where the longitudinal axis X3 is centred on the longitudinal axis X2, in particular centred in the housing 211 of the support 21, allowing for radial clearances between the external collar 257 and the internal radial surface 233 of the flange 23.

As shown in FIG. 1, in a configuration characterising the start of coupling, the longitudinal axis X3 and the longitudinal axis X1 are not necessarily aligned and may have an angular and/or radial misalignment or error. Advantageously, the angular errors between the fluidic connection device 2 and the complementary connection device 3 are of the order of 6° maximum and the radial errors between the fluidic connection device 2 and the complementary connection device 3 are of the order of 3.75 mm maximum.

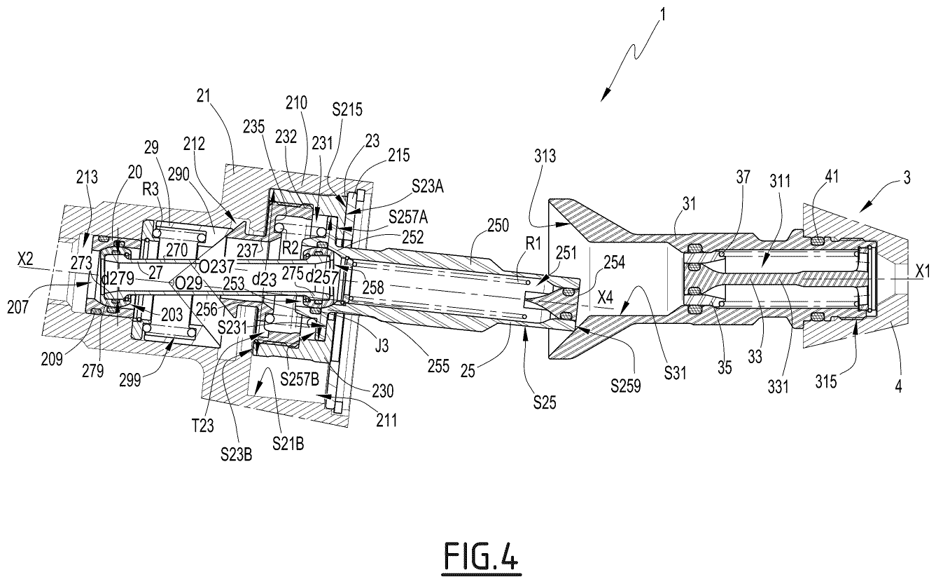

As represented in FIG. 4, when the female bodies 31 and the support 21 are brought together so as to achieve a first intermediate coupling configuration, the front end 259 of the nozzle 25 is engaged in the main body 311 and, by cooperation with the mouth surface 313, is guided towards the longitudinal axis X1, which causes the radial movement of the flange 23 in the support 21, a tilting motion of the rod 27 in relation to the nozzle 25, of the rod 27 in relation to the flange 23, and of the rod 27 in relation to the support 21. The front end 275 of the rod 27 effectively follows the movement of the rear end 252 of the nozzle 25 relative to the support 21, radially to the longitudinal axis X4 of the nozzle. During these movements, the sealing continues to be maintained between the nozzle 25 and the tubular body 270 of the rod 27 and between the tubular body 270 of the rod 27 and the support 21. The slider 20 moves in the proximal internal conduit 213 along the longitudinal axis X2. The spring R2 maintains the external collar 257 in surface contact with the internal surface S231 of the flange 23. During this radial movement of the flange 23 in the support 21, the rear surface S29B moves relative to the front surface S29A, such that their cooperation takes place by means of point contact.

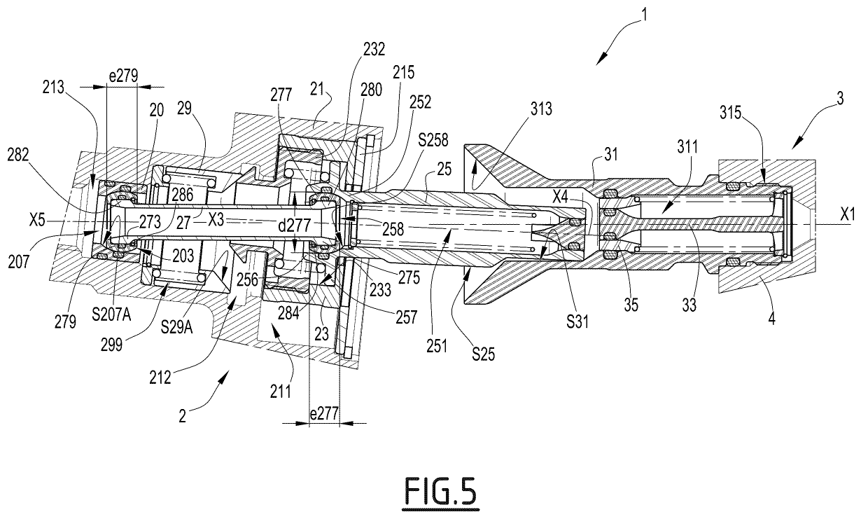

If the maximum radial movement is attained, that is to say the flange 23 comes into radial contact with the second internal radial surface S21B of the support 21 while the nozzle 25 is not coaxial with the longitudinal axis X1 of the main body 31, as represented in FIG. 5, the continuation of the coupling, in order to attain a second intermediate coupling configuration, will cause the angular movement of the nozzle 25 relative to the flange 23 against the spring R2, and therefore the angular movement of the nozzle 25 relative to the rod 27, and the longitudinal movement of the rod 27 and of the slider 20 relative to the support 21. During these movements, the sealing continues to be maintained between the nozzle 25 and the tubular body 270 of the rod 27 and between the tubular body 270 of the rod 27 and the support 21.

The angular and/or longitudinal movement of the external collar 257 of the nozzle 25 relative to the flange 23 is limited rearwards by the rear internal shoulder 232 of the flange 23. The nozzle 25 then aligns with the internal channel 311 of the main body 31; the nozzle 25 is then in a misaligned position in relation to the flange 23, that is to say the longitudinal axis X3 and the longitudinal axis X4 are inclined in relation to each other. The valve 254 comes into contact with the central piston 33 of the main body 31 while the annular valve 35 of the main body 31 comes into contact with the tubular body 250 of the nozzle 25, with the valve 254 and the annular valve 35 of the main body 31 being respectively pushed back against their spring to their retracted position in order to allow fluid to pass through between the proximal internal conduit 213 of the support 21 and the internal channel 311 of the main body 31, via the intermediate internal channel 271 of the rod 27 and via the distal internal channel 251 of the nozzle 25. The external radial surface S25 of the nozzle 25 comes into sealing cooperation with the internal radial surface S31 of the main body 31 via a sealing ring J5 borne by the internal radial surface S31 before the valve 254, and the annular valve 35 respectively, loses the sealing with the tubular body 250, and the main body 31 respectively. The coupled configuration, as represented in FIG. 6, is attained upon the female body 31 and the support 21 being brought into a predetermined degree of proximity. The nozzle 25 is fluidically coupled to the complementary fluidic connection device 3. Advantageously, the fitting of the nozzle 25 into the main body 31 is facilitated by cooperation by means of form-fitting, that is to say by way of fitting of the diameters thereof, between the internal radial surface S31 of the main body 31 and the external radial surface S25 of the nozzle 25, thereby enabling guidance without getting jammed.

During uncoupling, an inverse sequence of movements occurs. Upon cooperation of the nozzle 25 with the mouth surface 313, the spring R2 is able to push the external collar 257 back into surface contact with the flange 23, in order to return the nozzle 25 to a position that is aligned with the flange 23, with the longitudinal axis X3 parallel to, or even coaxial with, the longitudinal axis X4.

Thanks to the recentring device 299 and the spring R2, in the uncoupled configuration, the longitudinal axis X3 is recentred on the longitudinal axis X2, and the longitudinal axis X4 is recentred on the longitudinal axis X3, that is to say the flange 23 is in a centred position in the housing 211 and the tubular body 250 of the nozzle 25 is in a centred position in the internal housing 231, allowing for radial clearances between the external collar 257 and the flange 23, which makes it possible to increase the misalignment between the fluidic connection device 2 and the complementary fluidic connection device 3 permissible by the fluidic connection assembly 1 at the start of coupling, and therefore to reduce the size of the mouth surface 313 of the complementary fluidic connection device 3.

The coupling sequence may occur first with the angular movement of the nozzle 25 relative to the flange 23 and then with the radial movement of the flange 23 in the support 21, or with a combination of the angular movement of the nozzle 25 relative to the flange 23 with a radial movement of the flange 23 in the support 21, as a function of the force developed by the spring R2 on the nozzle 25, the force developed by the spring R3 on the flange 23, and the pressure forces of the fluid within the interior of the fluidic connection device 2.

In all the configurations, all of the surfaces of the flange 23 are fluidically isolated from the distal internal channel 251 of the nozzle 25 and from the intermediate internal channel 271 of the rod 27. In all the configurations, the front end 277 of the rod 27 is in sealed cooperation with the rear end 252 of the nozzle 25, and the proximal internal conduit 213 is in fluidic communication with the distal internal channel 251 via the intermediate internal channel 271.

By way of a variant not represented, the return of the flange 23 to the centred position in the housing 211 of the support 21 is achieved by a deformable element, advantageously an elastomer or a spring, interposed between the rod 27 and the support 21, or between the flange 23 and the support 21.

By way of a variant not represented, the rod 27 is mounted around the nozzle 25, instead of being mounted in an internal housing of the nozzle 25, the rod 27 is mounted around the nozzle 25 in a sealed manner, with the possibility of tilting relative to the nozzle 25, and with the possibility of limited movement in all directions parallel to the longitudinal axis of the nozzle.

By way of a variant not represented, only one surface out of the front surface S29A of the recentring ring 29 and the rear surface S237 of the flange 23 is frustoconical, with the other surface being arranged so as to come into contact with the conical surface, for example by being a rounded surface.

By way of a variant not represented, the flange 23 is common to a plurality of nozzles, preferably two nozzles; with the flange 23 then comprising as many distinct internal housings 231, and the support then comprising as many distinct proximal internal conduits 213, each internal conduit of the support accommodating in a sealed manner a rod which is mounted in a sealed manner with the respective nozzle, with the possibility of relative inclination.

By way of a variant not represented, the rear sealing between the rod 27 and the support 21 is achieved by a sealing ring housed in a groove formed in the internal radial surface S213 of the proximal internal conduit 213 and cooperating with the slider 20.

By way of a variant not represented, the fluidic connection device 2 does not comprise a valve and/or the complementary fluidic connection device 3 does not comprise a valve either.

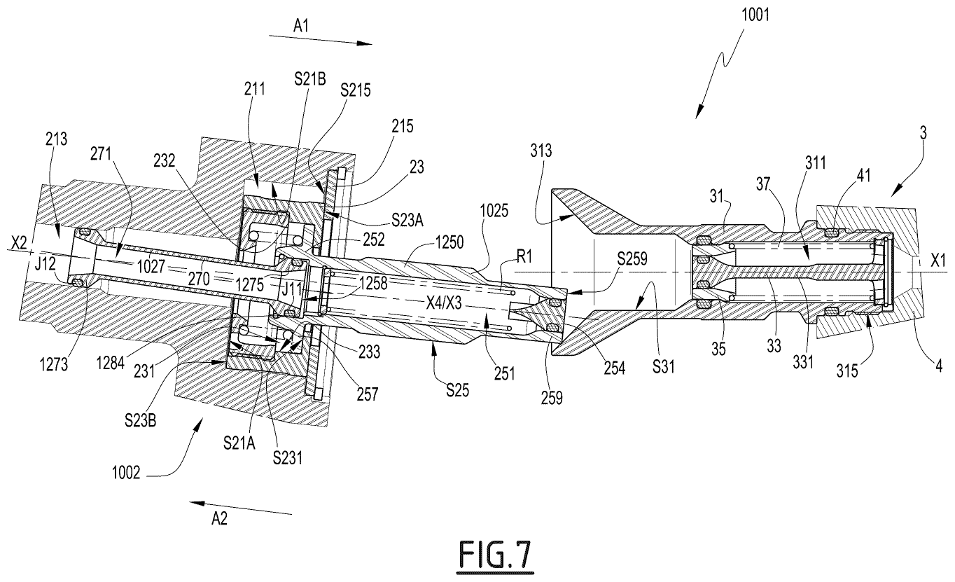

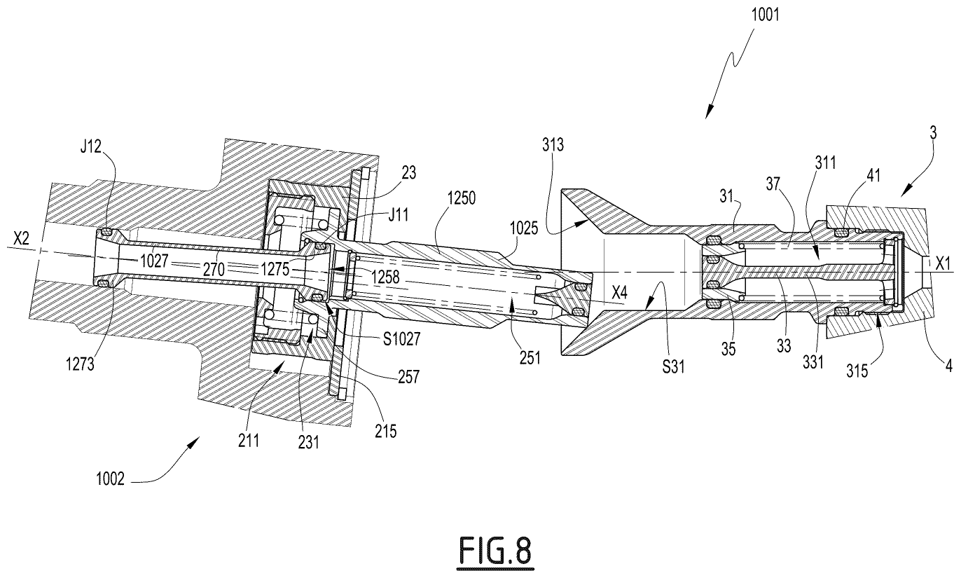

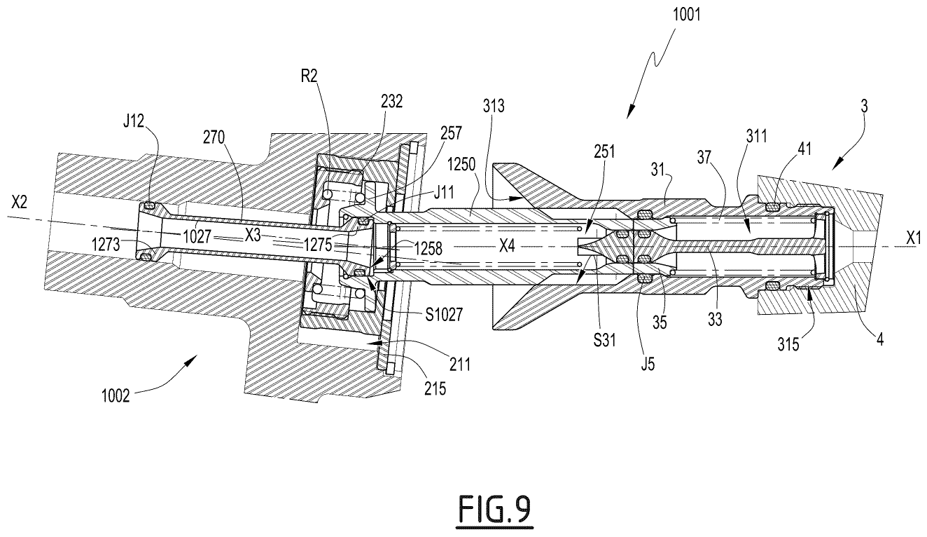

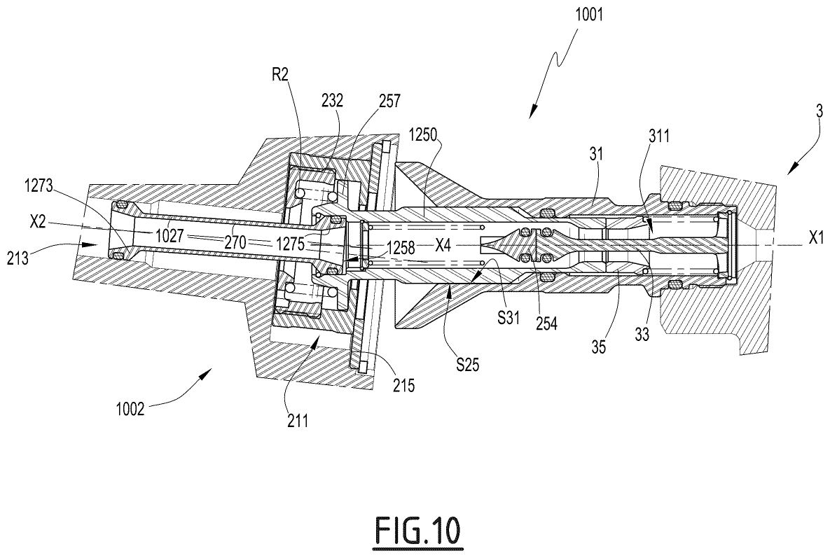

FIGS. 7 to 10 illustrate a fluidic connection assembly 1001 according to a second embodiment of the invention, the fluidic connection assembly 1001 being identical to the connection assembly 1 of the first embodiment except for the characteristic features described below. The reference indications for the fluidic connection device 1001 correspond to those of the fluidic connection device 1 when the referenced element is unchanged. The reference indications are increased by 1000 when they denote similar but modified elements in the connection device 1001.

The male tubular body 1250 comprises a cylindrical internal housing 1258 which opens onto the rear of the tubular body 1250 and which is intended to cooperate with the tubular body 270 of the rod 1027 via a sealing ring J11 housed in the external radial surface S1027 of the front end 1275 of the rod 1027. The rod 1027 is mounted in the internal housing 1258 of the tubular body 1250 by means of a stop segment 1284 which limits the relative longitudinal movement between the nozzle 1025 and the rod 1027 but which allows a tilting of the rod 1027 relative to the nozzle 1025. In effect, the radial dimensions of the front end 1275 of the rod 1027 and of the internal housing 1258 allow the longitudinal axis X4 to be inclined relative to the longitudinal axis X5. The front end 1275 of the rod 1027 is therefore mounted in the nozzle 1025 with the possibility of limited movement relative to the nozzle 1025 in all directions parallel to the longitudinal axis X4 and in all directions radial to the longitudinal axis X4, in a manner such as to allow the tilting of the rod 1027 relative to the nozzle 1025 while maintaining the front end 1275 in the nozzle 1025. In other words, allowing for operating clearances, the front end 1275 of the rod 1027 is integrally secured to the rear end 1252 of the nozzle 1025 along the longitudinal axis X4 and radially to the longitudinal axis X4. In the mounted configuration of the rod 1027 as mounted in the nozzle 1025, whatever their relative position, the sealing ring J11 ensures sealing cooperation between the front end 1275 of the rod 1027 and the nozzle 1025, and the distal internal channel 251 is in fluidic communication with the intermediate internal channel 271. The rear end 1273 of the tubular body 270 of the rod 1027 cooperates with the surface delimiting the proximal internal conduit 213 via a sealing ring J12 that is mounted in the rod 1027, thus integrally secured to the rod 1027 along the longitudinal axis X2, and interposed radially directly between the tubular body 270 and the proximal internal conduit 213. The sealing ring J12 ensures sealed cooperation between the rear end 1273 of the rod 1027 and the support 21 whatever be their relative positions. Thus the front and rear rings and the slider are omitted in this embodiment.

In the uncoupled configuration, as the fluidic connection device 1002 does not comprise a recentring device, the flange 23 is not necessarily in a centred position in the housing 211 of the support 21, as illustrated in FIG. 7, it being possible for its position in the housing 211 of the support 21 to depend on a previous coupling sequence.

The coupling sequence is identical to that described for the first embodiment. When uncoupled, the flange 23 remains in its relative position in the housing 211 of the support 21.

This construction also allows for angular and radial misalignment between the connection devices to be coupled.

Any characteristic feature described above for one embodiment or variant is applicable to the other embodiments and variants described above, insofar as said feature is technically feasible.

What is claimed is:

1. A fluidic connection device, comprising:
a flange, forming an external front axial surface and an external rear axial surface, opposite the external front axial surface, the external front axial surface and the external rear axial surface being annular, perpendicular to a central longitudinal axis of the flange, and oriented to be faced respectively in a frontward direction parallel to the longitudinal axis of the flange, and in a rearward direction opposite the frontward direction; and
at least one nozzle centred around a longitudinal axis, through which passes a distal internal channel, and which is configured so as to be fluidically coupled to a complementary connection device, the nozzle comprising:
a rear end, mounted in an internal housing of the flange; and
a front end, disposed beyond the external front axial surface of the flange in the frontward direction;
the nozzle being mounted in the flange:
with the possibility of tilting relative to the flange; and
with the possibility of limited movement relative to the flange in the frontward and rearward directions and in all the directions radial to the longitudinal axis of the flange;
the rear end of the nozzle being integrally secured in movement with the flange radially to the longitudinal axis, allowing for radial clearances between an external collar of the nozzle and the flange, the external collar being cylindrical and arranged at the rear end of the nozzle;
a cover, which forms a rear axial surface capable of cooperating with the external front axial surface of the flange in order to guide a movement of the flange relative to the cover radially to the longitudinal axis of the flange,
wherein the fluidic connection device includes a rod comprising:
an intermediate internal channel;
a front end, mounted in sealed cooperation with the rear end of the nozzle with the possibility of tilting of the rod relative to the nozzle and relative to the flange, the front end of the rod being integrally secured to the rear end of the nozzle along the longitudinal axis of the nozzle, allowing for operating clearances, and the front end of the rod being integrally secured to the rear end of the nozzle radially to the longitudinal axis of the nozzle, allowing for operating clearances, for fluidic communication between the distal internal channel of the nozzle and the intermediate internal channel of the rod; and
a rear end disposed beyond the flange, along the rearward direction for fluidic communication between the intermediate internal channel of the rod and a proximal internal conduit, relative to which the cover is intended to be immovable;
with the intermediate internal channel passing through the rod from the front end of the rod to the rear end of the rod.

2. A fluidic connection device according to claim 1, wherein the front end of the rod is received in a sealed manner in an internal housing of the rear end of the nozzle.

3. A fluidic connection device according to claim 2, wherein the rod comprises a tubular body and a front ring, which in a sealing manner surrounds the tubular body of the rod in order to form the front end of the rod and which, in a mounted configuration of the rod as mounted in the internal housing:
presents an external surface in the form of a portion of a sphere which cooperates by means of form-fitting with an internal surface in the form of a portion of a sphere, of the inner housing of the rear end of the nozzle; and
is able to effect a rearward abutment against an abutment surface formed by the partially spherical internal surface of the internal housing and delimited by an opening of the nozzle that opens onto the rear of the nozzle and, at the front, into the internal housing of the nozzle,
said opening extending, in a plane perpendicular to the longitudinal axis of the nozzle, over a cross section that is greater than the external cross section of the front ring, considered in a longitudinal plane passing through the longitudinal axis of the nozzle and in the mounted configuration of the rod as mounted in the internal housing.

4. A fluidic connection device according to claim 1, wherein no sealing ring is interposed directly between the flange and the nozzle.

5. A fluidic connection device according to claim 1, comprising a first spring, which is interposed between the flange and the nozzle and which resiliently biases the nozzle relative to the flange, to a position wherein the external collar of the nozzle is abutted frontward against an internal surface of the flange delimiting the internal housing, and the longitudinal axis of the flange is coaxial with the longitudinal axis of the nozzle.

6. A fluidic connection device according to claim 1, comprising a support body, having the cover attached therewith, that forms:
a front axial surface which delimits, together with the rear axial surface of the cover, a housing that receives the flange, the front axial surface being capable of guiding the movement of the flange relative to the support body, radially to the longitudinal axis of the flange, by cooperation with the external rear axial surface of the flange; and
the proximal internal conduit, which is centred around a central longitudinal axis, which opens into the housing of the support body in the frontward direction, and which receives the rear end of the rod for fluidic communication between the intermediate internal channel of the rod and the proximal internal conduit.

7. A fluidic connection device according to claim 6, comprising a recentring device, which resiliently biases the flange to a position wherein the longitudinal axis of the flange is coaxial with the central longitudinal axis of the proximal internal conduit.

8. A fluidic connection device according to claim 7, wherein the recentring device comprises:
a recentring ring, which is arranged in the proximal internal conduit and is movable in translational motion relative to the support body along the central longitudinal axis of the proximal internal conduit; and
a second spring, which pushes a front surface of the recentring ring into contact with a rear surface of the flange;
and wherein the rear surface of the flange is a frustoconical surface centred on the longitudinal axis of the flange and/or the front surface of the recentring ring is a frustoconical surface centred on the central longitudinal axis of the proximal internal conduit.

9. A fluidic connection device according to claim 6, comprising a sealing ring, that is integrally secured to the rod along the central longitudinal axis of the proximal internal conduit and in sealed contact with an internal radial surface of the proximal internal conduit of the support body.

10. A fluidic connection device according to claim 6, wherein the rear end of the rod is mounted in a slider:
in a sealed manner,
with the possibility of tilting relative to the slider,
wherein the rear end of the rod is integrally secured to the slider along the longitudinal axis of the proximal internal conduit, allowing for operating clearances, and the rear end of the rod is integrally secured to the slider radially to a longitudinal axis of the rod, allowing for operating clearances; and
wherein the slider has a cylindrical external radial surface and is mounted in the proximal internal conduit with the possibility of movement relative to the support body along the central longitudinal axis of the proximal internal conduit.

11. A fluidic connection device according to claim 1, wherein the intermediate internal channel of the rod is delimited by an internal surface, that is frustoconical and outwardly flared towards the exterior of the intermediate internal channel, at the front end of the rod, and at the rear end of the rod respectively.

12. A fluidic connection device according to claim 1, wherein a length of the rod, as measured between the front end and the rear end of the rod along a longitudinal axis of the rod, is strictly less than a length of the nozzle, as measured between the front end and the rear end of the nozzle along the longitudinal axis of the nozzle.

13. A fluidic connection device according to claim 1, comprising a valve disposed in the distal internal channel of the nozzle, which is movable relative to the nozzle along the longitudinal axis of the nozzle between an advanced position for closing the distal internal channel and a retracted position for opening the distal internal channel.

14. A fluidic connection assembly, comprising the fluidic connection device according to claim 1 and the complementary connection device, configured so as to be coupled with the nozzle of the fluidic connection device.

15. A fluidic connection assembly according to claim 14, wherein the complementary connection device includes a main body, that comprises a stepped internal radial surface, wherein the nozzle comprising a stepped external radial surface, and wherein the stepped internal radial surface and the stepped external radial surface cooperating, in the coupled configuration, by means of form-fitting.
